(19) United States
(12) Patent Application Publication
(10) Pub. No.: US 2010/0258859 A1
(43) Pub. Date: Oct. 14, 2010

(54) METHOD FOR FABRICATING SEMICONDUCTOR DEVICE HAVING LOW CONTACT RESISTANCE

(75) Inventor: Hyung Jin Park, Icheon-si (KR)

Correspondence Address: AMPACC Law Group, 3500 188th Street S.W., Suite 103, Lynnwood, WA, 98037, US

(73) Assignee: Hynix Semiconductor Inc., Icheon-si (KR)

(21) Appl. No.: 12/495,704

(22) Filed: Jun. 30, 2009

(30) Foreign Application Priority Data
Apr. 9, 2009 (KR) 10-2009-0030907

(51) Int. Cl. H01L 29/78; H01L 21/336

(52) U.S. Cl. 257/330; 438/270; 257/E29.262; 257/E21.41

(57) ABSTRACT

Disclosed herein is a method for forming a semiconductor device capable of reducing contact resistance in a highly integrated semiconductor device. The semiconductor device according to an exemplary embodiment of the invention includes an active region defined by an isolation film, the active region having porous regions therein, and gate patterns formed over the active region.

### CROSS-REFERENCE TO RELATED APPLICATIONS

Priority to Korean patent application No. 10-2009-0030907, filed on Apr. 9, 2009, the disclosure of which is incorporated herein by reference in its entirety, is claimed.

### BACKGROUND OF THE INVENTION

The present invention relates to semiconductor devices, and more particularly, to techniques associated with fabrication methods of a semiconductor device, which can reduce resistance generated conductive layers.

Semiconductor devices are designed to operate according to a given purpose which is determined through either implanting impurities or depositing a new material into or over a certain region in the silicon wafer. The semiconductor memory device is a common semiconductor device designed to store data. A semiconductor memory device is formed of many elements such as transistors, capacitors, resistors, etc., and connecting lines electrically connecting the elements

There has been a continuous effort for forming more chips on a given size of wafer. Smaller design rule has been sought to increase the degree of integration. Also, there has been an increasing demand for a semiconductor device that consumes less power.

For higher integration, it is necessary to reduce length and width of the connecting line as well as the size of each element in the semiconductor device. Accordingly, the size of contact connecting between each element and each line also shrinks down. However, when the contact size decreases, resistance between conductive layers connected to the contact increases. The increased resistance slows the data transfer rate and increases power consumption. Thus, a highly integrated device results in deteriorated operating speed and increased power consumption.

The process for forming a storage node contact in a conventional semiconductor memory is as follows. First, an isolation film for defining an active region and a gate pattern are formed on a semiconductor substrate. A first and a second source/drain regions are formed on one side and on the other side of the gate pattern, respectively, and the first and the second source/drain regions each are connected to a storage node contact and a bit line contact, respectively. To form the storage node contact, an insulating film is first deposited over the active region including the gate pattern, and the insulating film is then selectively removed so as to expose the first source/drain region. Then, the exposed region is filled with conductive material. Here, the insulating film preferred has good gap-fill properties so as to prevent void formation. Typically, an oxide such as BPSG (Borophospho Silicate Glass) is used.

However, as recent semiconductor memories have a higher degree of integration, the spacing between gate patterns has become narrower, thereby reducing the planar area of a region where the storage node contact should be formed. In particular, a decrease in the planar area has brought more difficulties in exposing the source/drain regions by completely removing the insulating film with thickness greater than the height of the gate patterns. This is because the gate patterns which are being protected by the insulating film deposited thereon should not be damaged when the insulating film is etched to form a region for a storage node contact.

In the etching process, a hard mask film is deposited over the insulating film and the hard mask film is then etched with a photoresist film that is patterned by an exposure process using a mask defining the storage node contact. Later, using the etched hard mask film as an etching mask, the insulating film is selectively removed. At this time, if alignment error occurs or if there is an error in the size of the gate patterns or the hard mask film's pattern with an engraved position of the storage node contact, it is highly possible that when the insulating film is etched the gate patterns may easily be exposed and get damaged, and the active region in contact with the storage node contact may not be exposed as much as desired.

Moreover, when a cell spacer nitride or a gate spacer nitride for protecting the gate patterns exist, it is harder to expose the active region for forming a storage node contact. That is to say, during the etching process, the insulating film, the cell spacer nitride or the gate spacer nitride, and the like, are likely to be over-etched or under-etched.

In addition, since the insulating film, the cell spacer nitride or the gate spacer nitride has a different etch rate from each other, etching condition should be changed in the middle of the etching process, thus requiring more process time. When the etching process is performed for a longer time, the spacer and the hard mask film, provided on the sidewall of the gate pattern and over the top of the gate pattern respectively, are more likely damaged. These damages result in a defect in a semiconductor device and can impair the reliability thereof. Also, when damages occur in the course of forming the storage node contact, a process margin for the subsequent process is decreased. As the magnitude of a charge and source voltage for data are decreased, those problems described above may significantly impair the operating reliability of the semiconductor device. If the storage node contact is not properly formed, data may be destroyed or distorted due to increased contact resistance, and possible damages to word lines (gate pattern) may deter proper operation of a cell transistor, causing an operation error.

### SUMMARY OF THE INVENTION

To overcome problems in the prior art as discussed above, the present invention is directed to a semiconductor device fabrication method capable of increasing junction surface between a contact and an active region by forming a porous layer in the source/drain regions in the active region and joining it with the contact, so as to reduce resistance by junction between the active region and the contact in the formation of contact to connect two conductive layers in a highly integrated semiconductor device.

The present invention provides a semiconductor device comprising: an active region defined by an isolation film, the active region having porous regions therein; and a gate pattern formed over the active region.

Preferably, the gate pattern is positioned between the porous regions.

Preferably, the gate pattern in a cell region has a recess gate structure that is formed at a deeper level than the porous region, and the gate pattern in a peripheral region is formed over a planar channel region.

Preferably, the porous region has a depth of about 150 Å to about 500 Å.

Preferably, the depth of the porous region is less than an ion implantation depth in source/drain regions.

Preferably, the semiconductor device further comprises a contact made from a conductive material to fill voids in the porous region.

Further, the present invention provides a method for fabricating a semiconductor device, comprising: forming an isolation film to define an active region at a semiconductor substrate; and forming porous regions and a gate pattern in the active region, the gate pattern being positioned between the porous regions.

Preferably, the gate pattern in a cell region is one of a recess gate and a buried-type gate, and the gate pattern in a peripheral region is formed over a planar channel region.

Preferably, in the cell region, the porous region is formed over the entire top portion of the active region; and, in the peripheral region, the porous region is formed in only a part of the active region.

Preferably, the porous region formation comprises: depositing a hard mask film over the isolation film and the active region; pattering the hard mark film to expose the location of the porous region; and performing an electrochemical etching process on the exposed active region to form a micro-pore structure.

Preferably, a pad nitride film is formed between the active region and the hard mask film, and the pad nitride film is etched by the patterned, hard mask film.

Preferably, the hard mask film is an amorphous carbon film.

Preferably, the electrochemical etching process is carried out in presence of HF solvent.

Preferably, pore size in the micro-pore structure is determined by current density during the electrochemical etching process.

Preferably, in the method for forming a semiconductor device, the porous region formation in the active region further comprises: oxidizing only a top portion of the micro-pore structure to form a thermal oxide film, or depositing an insulating film over a top portion of the micro-pore structure.

Preferably, due to the micro-pore structure, voids are generated below the thermal oxide film or the insulating film.

Preferably, the method for forming a semiconductor device further comprises: depositing an insulating film over a top portion of a structure including the gate pattern; etching the insulating film formed between the gate patterns to expose the porous region; and depositing a conductive material for use in filling the voids in the porous region to form a contact.

Preferably, the porous region includes the thermal oxide film on a top portion thereof, the thermal oxide film being removed following the insulating film etching process.

As the present invention forms a porous region for the active region in the highly integrated semiconductor device, the insulating film over the top is easily removed such that there is no need to change etching conditions and continue the etching process for a long period of time so as to sufficiently expose the active region when etching a region for a contact.

Furthermore, since the porous region in the active region is filled with a conductive material to form a contact, increasing the junction surface between the active region and the contact, it is possible to reduce the resistance by junction between the active region and the contact, and this helps to reduce the current leakage and increase the signal transfer rate.

### BRIEF DESCRIPTION OF THE DRAWINGS

FIGS. 1a to 1c are perspective views and a sectional view for explaining an active region in a semiconductor memory in accordance with an embodiment of the present invention; and

FIGS. 2a to 2b are sectional views for explaining a method of forming a contact on the top of the active region shown in FIG. 1.

### DESCRIPTION OF SPECIFIC EMBODIMENTS

Hereinafter, a method for forming a semiconductor device according to the present invention will be described in detail with reference to the accompanying drawings. However, the present invention is not limited to the embodiments disclosed below but may be implemented into different forms. These embodiments are provided only for illustrative purposes and for full understanding of the scope of the present invention by those skilled in the art. In the following description, same drawing reference numerals are used for the same elements.

In a semiconductor device according to one embodiment of the present invention, part of one side of the conductive layer is etched to form a porous region in a region where a contact for connecting two or more different conductive layers is supposed to be formed and the porous region is filled with conductive material, such that the junction surface between the region for the contact and the contact itself is increased to reduce resistance by junction. In particular, this is applied to a storage node contact for connecting a cell capacitor and a source region of cell transistor within a unit cell included in the semiconductor memory so as to minimize current leakage due to junction-resistance. This increases data retaining time in the unit cell, and facilitates data input/output process. Hereinafter, exemplary embodiments of the present invention will be described in detail with reference to accompanying drawings.

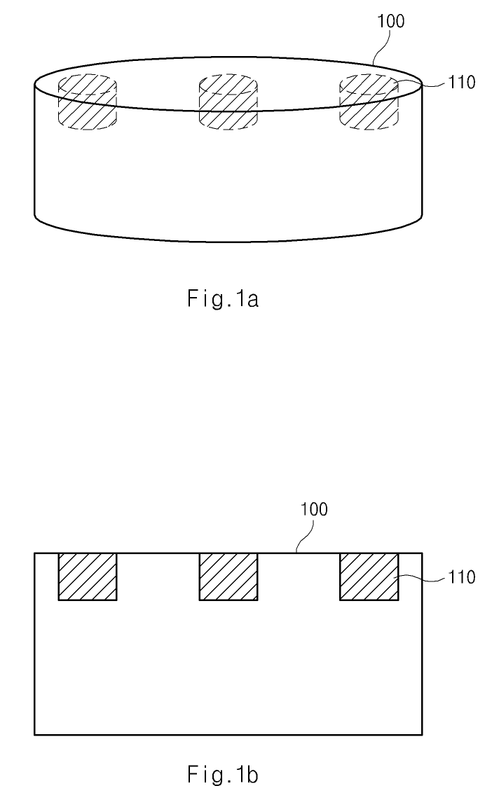

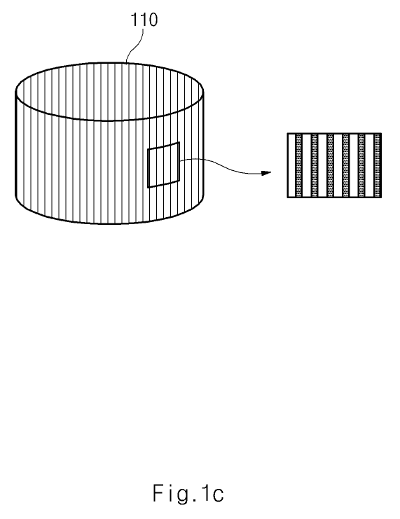

FIGS. 1a to 1c show an active region 100 in a semiconductor memory in accordance with one embodiment of the present invention

First, FIG. 1a shows an active region 100 formed over a semiconductor substrate. When an isolation film (not shown) is formed to define the active region 100 over the semiconductor substrate, a plurality of island type active regions 100 are formed. Generally, when a bulk silicon substrate is used, a trench is formed at a depth of 3000 Å or more in the semiconductor substrate and then the trench is filled with insulating material to form an isolation film. Therefore, as shown in FIG. 1a, the active region is formed in a pillar shape. Meanwhile, when an SOI substrate is used to form a semiconductor device, an active region is defined in an upper silicon layer (typically, this has a thickness of about 1500 Å) which is formed over a buried insulating film. Again, the isolation film for defining the active region is formed by removing the upper silicon layer to form a trench so as to expose a buried insulating film and then filling the trench with insulating material. Like the case using bulk silicon, the active region for the SOI substrate has a pillar shape as shown in FIG. 1a.

Referring to FIG. 1a, a porous region 110 is formed over the active region 100. The porous region 110 is formed in the regions corresponding to source/drain regions in the active region 100.

FIG. 1b shows the cross-section of the active region 100 of FIG. 1a. Formed in the active region 100 are three porous regions 110, and two gate patterns are formed between the porous regions 110.

FIG. 1c shows a perspective view and a sectional view of the porous region 110 shown in FIG. 1a. The porous region 110 has a plurality of micro pores arranged along the direction perpendicular to the surface of the semiconductor substrate. When seen from the top, the porous region 110 has a plurality of micro holes, and its cross-sectional surface shows a plurality of micro silicon pillars. The porous region may be of different configuration in another embodiment.

The following will now explain a method for forming the porous region 110 as illustrated in FIGS. 1a to 1c.

First, an isolation film is formed by a STI process to define the active region 100 over the semiconductor substrate. To be specific, a pad oxide film (not shown) and a pad nitride film (not shown) are formed over the semiconductor substrate, and a first hard mask film (not shown) is deposited on the pad nitride film. The hard mask film is then patterned using a mask defining the active region 100, and the patterned first hard mask film is used as an etch mask to form a trench in the semiconductor substrate. The trench is filled with insulating material, and then is planarized until the pad nitride film is exposed, thereby forming the isolation film.

Next, the patterned first hard mask film on the active region 100 is removed. Then, a second hard mask film (not shown) is deposited over the pad nitride film in the active region 100. The second hard mask film is made of an amorphous carbon layer and is deposited at a thickness of about 2000 Å. After that, the second hard mask film is patterned using a mask defining a source/drain region. Using the patterned second hard mask film as an etch mask, the pad nitride film and pad oxide film are etched to expose part of the active region 100.

Then, an electrochemical etching process is performed in the presence of HF solvent. Micro pores are created along the direction vertical to the surface of the substrate. The size of micro pore is determined by current density applied to the rear surface of the substrate during the electrochemical etching process. Particularly, while the amorphous carbon layer hardly melts in the presence of the HF solvent, micro F-ions produced from electrical decomposition of the HF solvent etch silicon substrate exposed in active region 100 to form a plurality of micro porous tubes in the active region 100. This porous region 110 is made to have a depth deeper than the depth of ion implantation of the source/drain regions.

Referring to FIGS. 1a to 1c, although the porous region 110 is formed by exposing part of the active region 100, in another embodiment of the present invention the porous region may also be formed by exposing the entire active region in the cell region, not the peripheral region. In the peripheral region, instead of forming the gate electrode after forming a recess in the active region, such as a recess gate or a buried-type gate, the gate electrode is formed after forming a channel region on the planar surface, so the porous region should not be formed at a location where the gate electrode is to be formed. However, in the cell region, a recess is formed in the active region so as to form the gate electrode, so, even if the porous region may be formed in the entire active region, the porous region that is formed in a region reserved for the gate electrode gets removed due to recess formation. Accordingly, in the fabrication process of a semiconductor device, if the porous region is formed in the entire active region after opening only the cell region, the process margin of the mask process can be improved further.

Although all steps of the process for forming the porous region 110, for example depositing various kinds of materials or etching, are not shown in detail in the drawing, since the present invention uses no atypical or difficult process, a person skilled in the art may fully understand how the porous region 110 is formed.

Once the porous region 110 is formed in the active region 100, subsequent process for forming gate patterns or the like should proceed. However, when the subsequent process proceeds with voids between micro silicon pillars in the porous region 110, not only various matters invade into the voids, but it is also difficult to remove those invaded matters. To avoid this, the present invention oxidizes only the top portion of the porous region 110 to form a thermal oxide film. This thermal oxide film can protect the porous region 110 during the gate pattern formation process, and ensures process margin at the time of etching for forming a contact.

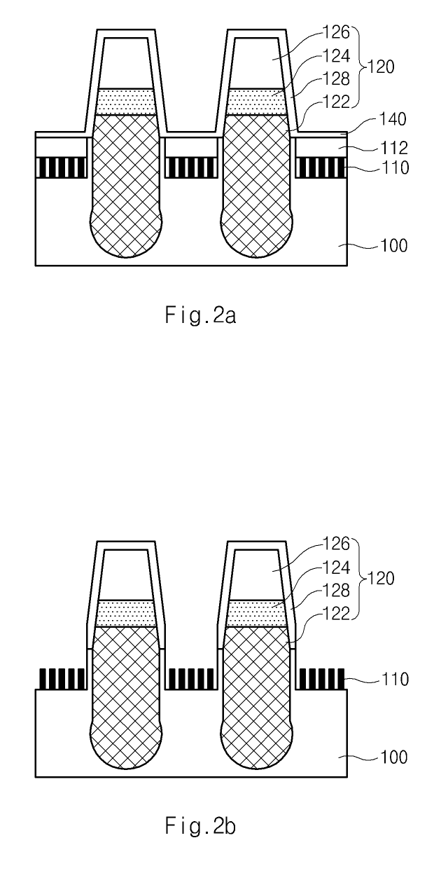

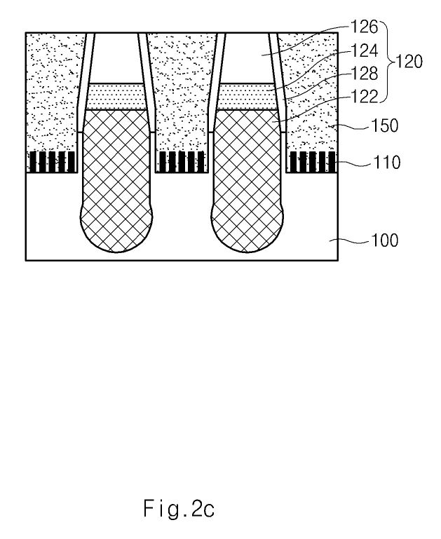

FIGS. 2a to 2b are sectional views for explaining the method of forming a contact for the semiconductor memory at the top of the active region shown in FIG. 1.

Referring to FIG. 2a, over an active region 100 are formed gate patterns 120 between porous regions 110. Before the gate patterns 120 are formed, the top of the porous region 110 is transformed to a thermal oxide film 112 to protect the bottom of the porous region 110. Since the process margin at the time of etching for contact formation may vary depending on the thickness of the thermal oxide film 112, it is possible to make the thermal oxide film 112 formed at a thickness of 20-60% of the depth of the porous region 110. A gate oxide film (not shown) is formed between the substrate in the active region 100 and the gate pattern 120, the gate pattern 120 including a gate lower electrode 122, a gate upper electrode 124, a gate hard mask 126 and a gate spacer nitride film 128. Since the method of forming the gate oxide film and the gate pattern 120 are not much different from that of the conventional semiconductor device, a detailed description thereon is omitted. Then, a cell spacer nitride film 140 is deposited in order to protect the entire cell region. The cell spacer nitride film 140 is deposited at a thickness of about 100 Å, and the gate spacer nitride film 128 is deposited at a thickness of about 50 Å.

Referring to FIG. 2b, the cell spacer nitride film 140 and the thermal oxide film 112 are selectively removed so as to expose the porous region 110. In one embodiment of the present invention, the self align etching method using the gate pattern 120 is employed, and both of the cell spacer nitride film 140 and thermal oxide film 112, which have a different etch rate from each other, are etched with adjustment of the etch rate.

Because the top of the porous region 110 is formed of the thermal oxide film 112 according to the present invention, it is easier, compared with the prior art, to expose the source/drain region by etching away the thermal oxide film 112. In the case of the prior art, in order to completely remove the insulating material residues (e.g., the cell spacer nitride film, pad nitride film, pad oxide film, etc.) between the gate patterns to expose the source/drain region, the etch rate has to be changed during the etching process and the etching process has to be performed for a long time. In the case of the present invention, however, the etching process is simplified and the amount of time for the process is also reduced, and these are made possible because of the easily etchable thermal oxide film 122 formed over the porous region 110.

Furthermore, another embodiment of the present invention includes a process for depositing an insulating film using material with poor step coverage property over the porous region 110, instead of forming the thermal oxide film 122. The reason for using material with poor step coverage property is to avoid the insulating film from filling in and blocking the porous tube formed in the porous region 110. For instance, the insulating film is deposited by CVD (Chemical Vapor Deposition) such that the porous region 110 can be protected.

Referring to FIG. 2c, when the porous region 110 is exposed, conductive material 150 is then deposited over the porous region 110 to form a contact. At this time, the conductive material 150 fills in the micro porous tubes in the porous region 110. One example for doing that according to the present invention is depositing poly silicon using the ALD method. As a result, due to the micro porous tubes, a 3-dimensional junction, not a 2-dimensional planar junction, is formed between the conductive material 150 and the active region 100. Herein, the conductive material 150 is served as a contact such as a storage node contact or a bit line contact for connecting source/drain region to a capacitor or a bit line.

As explained so far, the prior art has difficulties to expose the active region by etching a number of thin films in the course of etching to form a contact between the gate patterns. Particularly, as the degree of integration of semiconductor devices increases, margin for the etching process becomes significantly decreased, thus making it difficult to expose the source/drain region or making the gate patterns damaged. However, in the present invention the etching process for contact formation was simplified by forming the porous region in the active region before forming the gate patterns and by making the top of the porous region into the thermal oxide film.

Furthermore, in the prior art the junction between the contact and the active region is in a 2-dimensional planar shape. Thus, if a sufficient portion of the active region is not exposed, the area of the junction surface is decreased, causing resistance between the contact and the active region increased. However, in the present invention, the junction between the active region and the contact forms a 3-dimensional junction, rather than a 2-dimensional planar junction, thereby significantly increasing the junction area so as to prevent junction resistance from being increased.

The exemplary embodiments of the present invention are illustrative and not limitative and those skilled in the art would appreciate that various modifications, changes, subtractions and additions are possible within the spirit and scope of the appended claims.

What is claimed is:

1. A semiconductor device, comprising:
an active region provided on a substrate;
a gate pattern formed on the active region; and
a source/drain region provided adjacent to the gate electrode, the source/drain region including a porous region.

2. The semiconductor device according to claim 1, wherein if at least two porous regions are included in the active region, the gate pattern is provided between the two porous regions.

3. The semiconductor device according to claim 2, wherein the gate pattern is a recess gate structure that extends deeper than the porous region.

4. The semiconductor device according to claim 3, wherein the porous region has a depth of about 150 Å to about 500 Å.

5. The semiconductor device according to claim 3, wherein the depth of the porous region is less than an ion implantation depth of the source/drain region.

6. The semiconductor device according to claim 1, further comprising a contact filling the porous region.

7. The semiconductor device according to claim 1, wherein the porous region includes a plurality of porous tubes arranged in a direction vertical to the surface of the substrate.

8. A method for fabricating a semiconductor device, comprising:
forming a plurality of porous regions on an active region; and
forming a gate pattern in the active region, the gate pattern being positioned between two adjacent porous regions.

9. The method according to claim 8, wherein the conductive material is filled into the porous material after the gate pattern has been formed.

10. The method according to claim 8, further comprising:
forming a first hard mask pattern over the porous regions; and
implanting ions into the porous regions to form source/drain regions.

11. The method according to claim 8, further comprising:
forming a thermal oxide layer over the porous region before forming the gate pattern.

12. The method according to claim 11, wherein the thermal oxide layer is formed by converting a portion of the porous region into an oxide layer.

13. The method according to claim 11, wherein the thermal oxide layer has a depth of 20-60% of that of the porous regions.

14. The method according to claim 9, wherein the forming porous layer comprises:
forming a second hard mask pattern exposing portions of the active region; and
performing an electrochemical etching process on the exposed active region to form a plurality of micro pores.

15. The method according to claim 14, wherein the electrochemical etching process is carried out by treating HF solvent on the exposed active region while applying an electrical potential to an opposing side of the substrate.

16. The method according to claim 15, wherein the diameter of the micro pores is controlled by an amount of the electrical potential applied during the electrochemical etching process.

17. The method according to claim 8, further comprising:
forming a hard mask pattern at least over the porous regions;
forming an insulating film over the gate pattern and the hard mask pattern;
etching the insulating film to form a spacer on the sidewalls of the gate pattern;
patterning the first hard mask pattern using the gate pattern and the spacer as an etching mask to expose the porous regions;
depositing conductive material to fill the pores in the porous regions to form a contact.

18. The method according to claim 18, wherein the hard mask pattern is a thermal oxide film that has been obtained by converting a portion of the porous regions into the thermal oxide film, wherein the thermal oxide film is removed the insulating film has been etched.
